(19) United States
(12) Patent Application Publication
(10) Pub. No.: US 2026/0052661 A1
(43) Pub. Date: Feb. 19, 2026

(54) EMC HOUSING, HOUSING PART OF AN EMC HOUSING AND USE

(71) Applicant: GKN Automotive Limited, Birmingham (GB)

(72) Inventors: Tobias Weling, Lohmar (DE); Marcel Szczurek, Lohmar (DE); Björn Nemitz, Lohmar (DE)

(21) Appl. No.: 19/300,756

(22) Filed: Aug. 15, 2025

(30) Foreign Application Priority Data
Aug. 16, 2024 (DE) 102024123435.0

(51) Int. Cl. H05K 9/00

(52) U.S. Cl. CPC H05K 9/0018; H05K 9/0049; H05K 9/0081

(57) ABSTRACT

An EMC housing for an electrical component, having at least a first housing part and a second housing part, which are connected to one another via a sealing surface and together enclose a volume of the housing in a liquid-tight manner. A plate-shaped third housing part is arranged between the first housing part and the second housing part within the volume. The third housing part has a plurality of elastically deformable contact elements in at least one connection region with at least one of the first housing part and the second housing part for forming an electrically conductive connection between the housing parts.

### CROSS REFERENCE TO RELATED APPLICATIONS

This application claims the priority to German Patent Application No. DE102024123435.0 filed on Aug. 16, 2024, and the content of this priority application is incorporated herein by reference in its entirety.

### TECHNICAL FIELD

The disclosure relates to an EMC housing, a housing part of an EMC housing and a use of an EMC housing. The housing or the housing parts serve in particular to ensure electromagnetic compatibility (EMC) in the arrangement of an electrical component by shielding it from an environment.

### BACKGROUND

The shielding of electrical or electrotechnical components serves to keep electrical and magnetic fields, particularly formed at higher frequencies, away from them or conversely to protect the environment from the fields emitted by the component.

In particular, shielding is provided by electrically conductive metal sheets, foils or layers (connected to earth or reference potential or ground). These include, for example, metal-coated plastic foils, paper laminated with aluminum foil, graphite and conductive lacquer layers. It is also known to coat plastic housings with a metallic layer.

The shielding is designed in particular as a housing or housing part, whereby the housing encloses a volume in which at least one electrical component (to be shielded) is arranged. The housing must also allow the components arranged in it to be attached, so that a so-called EMC mounting plate is often arranged inside the housing.

Such housings are usually made up of several parts. For example, the housing comprises a cover area (first housing part), a base area (second housing part) and a mounting plate (third housing part), which is arranged between the base area and the cover area. The mounting plate extends within the volume of the housing enclosed by the base area and cover area, forming partial volumes of the volume.

For electromagnetic shielding, it is important that the individual parts of the housing are connected to each other with the lowest possible impedance and form a common potential (ground connection). For this purpose, an electrically conductive connection of the individual housing parts with each other and with the ground or reference potential must be ensured.

The object of at least some implementations of the present disclosure is to solve at least in part the problems cited with reference to the prior art. In particular, a housing or a housing part for a housing is to be proposed which can be produced at low cost and at the same time enables effective shielding of an electrical component.

### SUMMARY

The features listed individually in the claims can be combined with each other in a technologically meaningful way and can be supplemented by explanatory facts from the description and/or details from the figures, whereby further embodiments of the disclosure are shown.

An EMC housing (hereinafter also referred to as “housing”) for an electrical component (e.g. an inverter, in particular an inverter used in a motor vehicle, a converter, etc.) is proposed.

The EMC housing comprises at least a first housing part and a second housing part, which are connected to each other via a sealing surface and together enclose a volume of the housing in a liquid-tight manner, wherein a plate-shaped third housing part is arranged within the volume between the first housing part and the second housing part. In at least one connection region with at least one of the first housing part and the second housing part, the third housing part has a plurality of elastically deformable contact elements for forming an electrically conductive connection between the housing parts. When the housing parts are connected to the housing, the contact elements are elastically deformed by the housing part contacting the respective contact element.

The EMC housing is in particular a dimensionally stable housing, which is therefore in particular not or only insignificantly elastic, but only plastically deformable. The same applies in particular to the first housing part, the second housing part and, to a limited extent, the third housing part.

The housing is used in particular to shield components arranged within the volume from the housing's surroundings/environment. In doing so, an influence on the environment due to the emission of electromagnetic radiation by components inside the housing, but also the influence on components arranged inside the housing due to electromagnetic radiation acting on the housing from the environment, must be taken into account. In addition, the housing should also allow the components arranged inside it to be attached, so that a so-called EMC mounting plate (third housing part) is often arranged inside the volume.

In particular, the housing parts are connected to each other in such a way that a uniform ground potential is achieved.

The first housing part is in particular a top side (upper half) or a cover part and the second housing part is a bottom side (lower half) or a base part. The first housing part and the second housing part are connected to each other in particular via a sealing surface and enclose the volume in a liquid-tight, possibly also gas-tight manner. The third housing part can at least form this sealing surface or be arranged (completely) inside the volume. The third housing part serves in particular as a mounting plate for components arranged within the volume. Alternatively or additionally, the third housing part serves to divide the volume into sub-volumes, whereby these are then shielded from each other by the third housing part.

The third housing part is particularly plate-shaped. In particular, it is designed as a sheet metal part.

In at least one connection region with at least one of the first housing part and the second housing part, the third housing part has a plurality of elastically deformable contact elements for forming an electrically conductive connection between the housing parts. In a connection region, the third housing part contacts either the first housing part or the second housing part or both housing parts. The third housing part contacts the first housing part in particular (exclusively) with an upper side and the second housing part in particular (exclusively) with a lower side.

The contact elements, via which the other housing parts are contacted, are in particular elastically deformable.

When the housing parts are connected to the housing, the contact elements are deformed at least or exclusively elastically (alternatively also plastically) by the housing part contacting the respective contact element. This means that the contact elements are in an undeformed state before the housing is assembled for the first time and are then deformed during assembly. In particular, this also means that the contact elements are under a preload when the housing is in an assembled state.

If the housing is disassembled again and the housing parts are separated from each other, the contact elements can deform elastically (at least partially).

In particular, the plurality of contact elements are arranged next to each other in the connection region (along an extension direction) and in each case separated from each other by at least (or exactly) one slit. Two or more slits can also be arranged at least between two contact elements of the plurality of contact elements, with differently shaped areas (differently shaped than the contact elements) of the third housing part being present between the slits.

In particular, a slit is an opening in the third housing part that extends from the top to the bottom of the third housing part. In particular, the slit is elongated, i.e. its length is greater by a factor of 2 to 50 than its breadth.

The slits of a connection area are in particular oriented essentially parallel to each other or extend essentially transverse to a straight or possibly also curved course (extension direction) of the connection region.

In particular, the slit extends in a straight line, but can also have a curved course along its length.

The slit serves in particular to ensure that the contact elements arranged between two slits can be deformed independently of each other or independently of the area of the third housing part surrounding them (elastically, possibly also plastically).

In particular, the contact elements are arranged next to each other in the connection region along an extension direction and the at least one slit has a length of 5 to 50 millimeters, in particular 10 to 30 millimeters, or 15 to 20 millimeters, extending transversely to the extension direction.

In particular, at least one of the contact elements between two slits has a width of 5 to 20 millimeters, in particular 7 to 15 millimeters.

In particular, the at least one slit has a breadth (extending transversely to the length) of zero to 5 millimeters, in particular from 0.2 to 5 millimeters, or from 0.4 to 2.5 millimeters. The breadth is particularly constant along the length. The slit can be created, for example, by separating the material (possible breadth of zero millimeters) or, for example, by removing the material (possible breadth of more than zero millimeters).

In addition to the (first) slits arranged between the contact elements, further (second) slits can also be provided, which are arranged in particular at the respective ends of the length of the (first) slits and extend transversely thereto. These (second) slits narrow, but do not cut through, a transition between the contact element and the flat area surrounding the contact element.

In particular, the above explanations apply to at least 40%, which may be at least 60%, or to at least 80% or even to all contact elements and/or slits.

In particular, the values for length, width and breadth are each measured in a projection of the described elements into a plane running transverse to the height direction.

In particular, the respective contact element is defined by the length of the slits and the width of the contact element, wherein the contact elements comprise between 0.5% and 80%, in particular between 5% and 20%, of a total area of the third housing part (i.e. area of the top side or area of the bottom side, in particular as a projection into a plane which is defined, for example, by the circumference of the third housing part).

In particular, the contact elements extend over 25 to 90%, in particular over 50% to 75% of the extent of the circumference of the third housing part.

In particular, the third housing part extends essentially in one plane. The third housing part has flat, planar areas on the one hand and contact elements or connection regions on the other. A height direction extends in particular transversely to the plane. In particular, the contact elements extend from a first height of the flat areas to a second height. The second height can be above or below the plane. A distance between the first height and the second height is in particular between 0.5 and 10 millimeters, or between 2 and 5 millimeters.

In particular, the surface of the contact element, i.e. between two slits and along the length, is curved, i.e. the contact element has a curved or otherwise curved course, e.g. sawtooth-like or zigzag-like or other course, along a direction running parallel to the slits. In particular, this forms a raised area with a different (second) height compared to the flat area (with a first height) surrounding the contact elements.

In particular, the contact elements are arranged next to each other in the connection region along an extension direction and are deformed relative to a height direction when the housing parts are interconnected. In an undeformed state (i.e. before the housing is joined together and before the contact elements are elastically deformed), the contact elements each have the same or different heights along the extension direction. The different heights can differ from one another by between 5% and 200%, in particular by between 50% and 150% of the maximum distance. On the one hand, this means that the contact elements extend in opposite height directions relative to the plane (first height) to a second height of the same absolute amount. On the other hand, this means that, for example, between two contact elements extending to the same second height, one contact element extends to a slightly lower second height. This means, for example, that the contact elements extending up to the greater height are more strongly (elastically) deformed than the contact elements extending up to the lower height.

In particular, of two contact elements arranged next to each other, a first contact element only contacts the first housing part and a second contact element only contacts the second housing part.

In particular, the third housing part extends in the connection region along an extension direction in a central plane and of two contact elements arranged next to each other, a first contact element is oriented from the central plane towards the first housing part and a second contact element is oriented from the central plane towards the second housing part. In particular, this means that these contact elements extend in opposite height directions relative to the plane or center plane (first height) to a second height of the same absolute amount or of a different absolute amount in each case.

In particular, the contact elements are arranged next to each other in the connection region along an extension direction and are deformed relative to a height direction by the connection of the housing parts. In particular, at least one contact element has a height that varies along the extension direction in an undeformed state. In particular, the contact element has a largest second height (hereinafter also referred to as maxima) adjacent to the two slits delimiting the contact element and a smallest second height (minimum) between these two largest second heights (maxima). In particular, this smallest second height (minimum) is also greater than a first height.

In particular, at least one contact element has a contact surface with a structure that contacts the respective housing part, whereby the structure contacts the housing part during the elastic deformation of the contact element and damages its housing part surface. Damaged means in particular that, for example, an oxide layer present on the housing part surface is broken by the edge and by the deformation of the contact element, so that an electrically conductive connection between the housing parts is ensured via the contact element.

The structure can, for example, have sharp edges (edge radius less than 0.2 millimeters, in particular less than 0.1 millimeters; adjacent surfaces of the edge have an angle of 20 to 160 degrees). The structure can be formed, for example, by the edges of the contact element adjacent to the slit. In the undeformed state (i.e. before the housing is assembled/joined and before the contact elements are elastically deformed), these edges are oriented towards the housing part so that the edge itself contacts the housing part. In particular, the surfaces of the contact element adjacent to the edge extend at an angle of at least 20 to 120 degrees to a contacted surface of the housing part (the housing part surface).

In particular, the third housing part is made of a metallic material. In particular, any electrically conductive material is suitable as a metallic material, especially with an electrical conductivity that is between that of aluminum (as a low-cost material) and that of copper (as a material with high conductivity).

In particular, the sealing surface between the first housing part and the second housing side is designed to be fully circumferential around the volume. The sealing surface therefore extends in particular around the respective housing part or the (partial) volume enclosed by it. The respective seal (e.g. a conventional, electrically non-conductive seal or a generally known, electrically conductive EMC seal) extends in particular along the sealing surface, in particular also fully circumferentially.

In particular, the electrically conductive connection between the first housing part and the second housing part is ensured by the third housing part. Connecting elements (e.g. screws or rivets), which are used to connect the first housing part to the second housing part, can also form an electrically conductive connection, but this is not usually sufficient for a low-impedance connection of the housing parts.

Furthermore, a housing part of the described EMC housing is proposed, wherein the housing part is the third housing part.

Furthermore, a use of the described EMC housing for an inverter as an electrical component is proposed.

In particular, the EMC housing is intended for arrangement in motor vehicles, especially as a housing for an electrical component that is used in connection with a traction drive or an electrical machine of the motor vehicle.

The explanations regarding the EMC housing are particularly applicable to the third housing part and its use and vice versa.

The use of indefinite articles (“an”, “a”), in particular in the claims and the description reproducing them, is to be understood as such and not as a number word. Accordingly, terms or components introduced with are to be understood in such a way that they are present at least once and, in particular, can also be present several times.

As a precaution, it should be noted that the number words used here (“first”, “second”, . . . ) are primarily (only) used to distinguish between several similar objects, quantities or processes, i.e. in particular they do not necessarily specify any dependency and/or sequence of these objects, quantities or processes in relation to one another. If a dependency and/or sequence is required, this is explicitly stated here or is obvious to the person skilled in the art when studying the specific embodiment described. Insofar as a component may occur more than once (“at least one”), the description of one of these components may apply equally to all or some of the majority of these components, but this is not mandatory.

### BRIEF DESCRIPTION OF THE DRAWINGS

The disclosure and the technical context are explained in more detail below with reference to the accompanying figures. It should be noted that the disclosure is not intended to be limited by the embodiments given. In particular, it should be noted that the figures and in particular the proportions shown are only schematic. They show:

FIG. 1: a known arrangement of an inverter and an electric motor;

FIG. 2: a side view of an inverter in section and an enlarged section;

FIG. 3: an inverter in a perspective view;

FIG. 4: a lower part of the inverter according to FIG. 2 in a sectional perspective view;

FIG. 5: a third housing part inserted in the inverter according to FIG. 4 in a top view;

FIG. 6: the enlarged section of FIG. 2, in a side view of the inverter in section;

FIG. 7: a detail of the inverter according to FIG. 2 in a perspective view in section;

FIG. 8: a first embodiment of contact elements in a view transverse to the extension direction;

FIG. 9: the contact elements according to FIG. 8 in a view along the extension direction;

FIG. 10: a second embodiment of contact elements in a view transverse to the extension direction;

FIG. 11: the contact elements according to FIG. 10 in a view along the extension direction;

FIG. 12: a section of a first embodiment of a housing before an assembly of the housing parts in a side view in section;

FIG. 13: the section according to FIG. 12 in the assembled state;

FIG. 14: a section of a second embodiment of a housing before assembly of the housing parts in a side view in section; and

FIG. 15: the section according to FIG. 14 in the assembled state.

### DETAILED DESCRIPTION

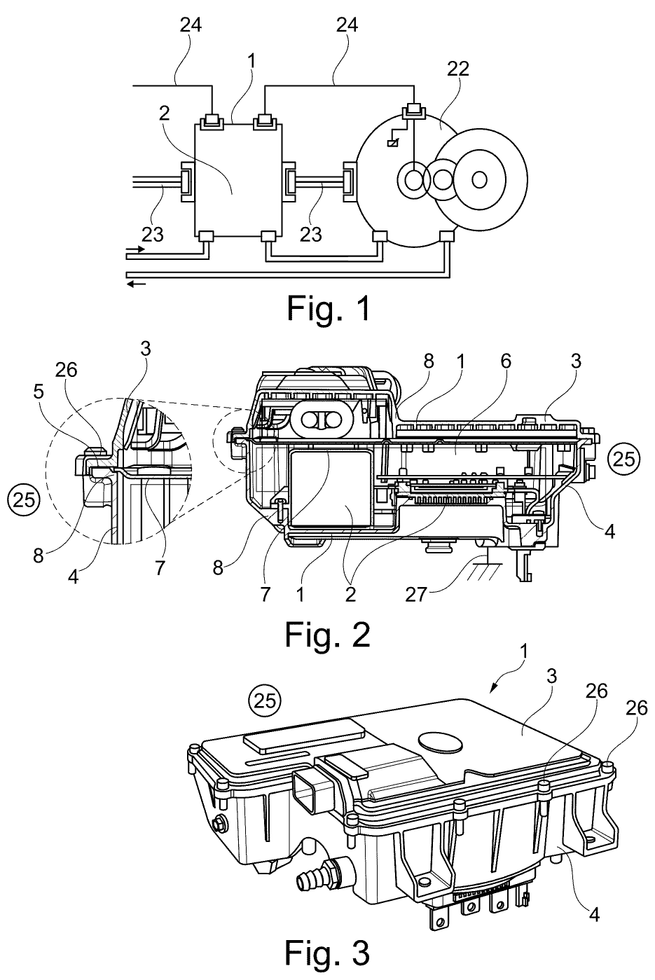

FIG. 1 shows a known arrangement of an inverter (electrical component 2) and an electric motor 22. The arrangement comprises the electrical component 2 with an EMC housing 1, the electric motor 22 and its electrical connections 23 and signal lines 24.

FIG. 2 shows a side view of an inverter in section and an enlarged section. FIG. 3 shows a perspective view of an inverter. FIGS. 2 and 3 are described together below. Reference is made to the comments on FIG. 1.

The electrical component 2 shown here as an inverter is arranged in an EMC housing 1. The housing 1 serves to ensure electromagnetic compatibility (EMC) in the arrangement of the electrical component 2 by shielding it against an environment 25.

The purpose of shielding electrical or electrotechnical components 2 is to keep electrical and magnetic fields, particularly formed at higher frequencies, away from them, or conversely to protect the environment 25 from the fields emitted by the component 2.

Shielding is provided by electrically conductive housing parts 3, 4, 7 connected to ground 27. The housing parts 3, 4 enclose a volume 6 in which the electrical component 2 (to be shielded) is arranged. An electrically conductive connection between each individual housing part 3, 4, 7 and the ground 27 must be ensured.

In the case of multi-part housings 1, the at least liquid-tight (possibly even gas-tight) sealing of the volume 6 enclosed by the housing 1 with respect to the environment 25 must also be ensured. It is known, for example, to provide an electrically non-conductive sealing element in the area of the sealing surface 5 of the housing parts 3, 4 in contact with each other, whereby the electrically conductive connection of the individual housing parts 3, 4 is then ensured, for example (only or essentially) via connecting elements 26, such as screws. Alternatively, a known EMC seal can be used in the area of the sealing surface.

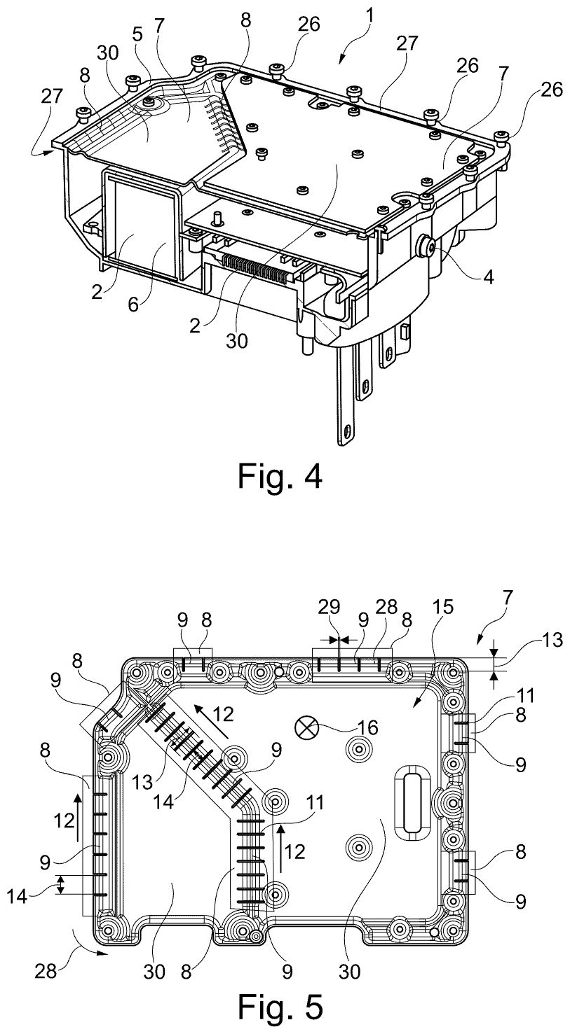

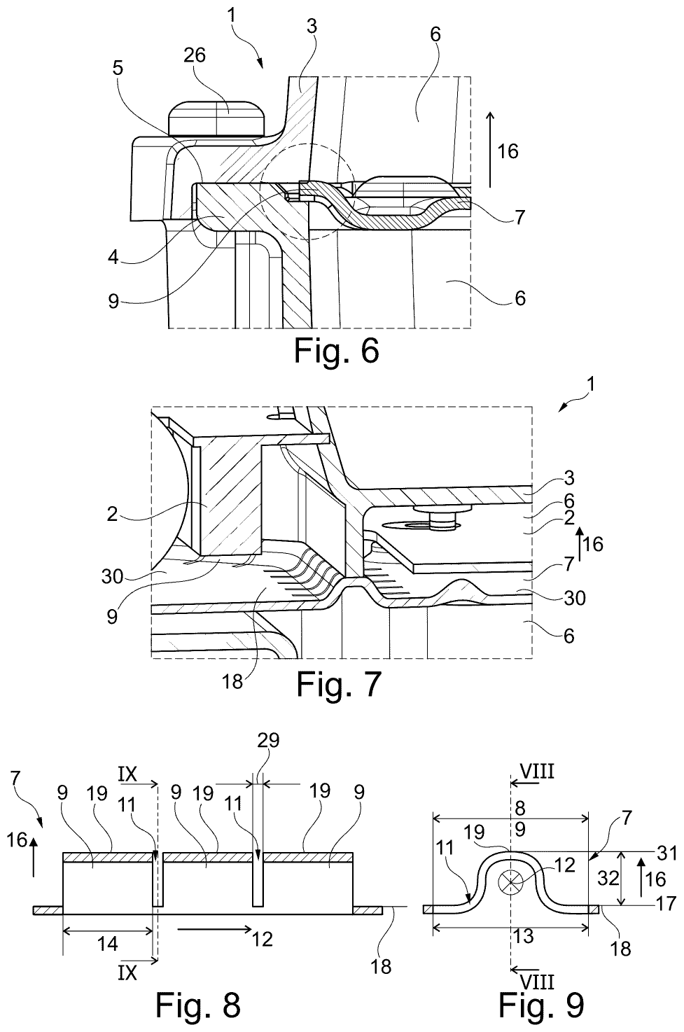

FIG. 4 shows a sectional perspective view of a lower part of the inverter according to FIG. 2. FIG. 5 shows a third housing part 7 inserted in the inverter according to FIG. 4 in a top view. FIG. 6 shows the enlarged section of FIG. 2, in a side view of the inverter in section. FIG. 7 shows a detail of the inverter according to FIG. 2 in a sectional perspective view. FIGS. 4 to 7 are described together below. Reference is made to the explanations of FIGS. 1 to 3.

The EMC housing 1 comprises a first housing part 3 (see FIGS. 2, 3 and 6) and a second housing part 4, which are connected to each other via a sealing surface 5 and together enclose a volume 6 of the housing 1 in a liquid-tight manner, a plate-shaped third housing part 7 being arranged between the first housing part 3 and the second housing part 4 within the volume 6. The third housing part 7 has a plurality of elastically deformable contact elements 9, 10 in several connection regions 8 with at least one of the first housing part 3 (e.g. FIG. 7) and the second housing part 4 to form an electrically conductive connection between the housing parts 3, 4, 7. When the housing parts 3, 4, 7 are assembled to form the housing 1, the contact elements 9, 10 are elastically deformed by the housing part 3, 4 contacting the respective contact element 9, 10.

The EMC housing 1 is a dimensionally stable housing 1, i.e. it is not or only insignificantly elastic, but only plastically deformable. The same applies to the first housing part 3, the second housing part 4 and, with restrictions, also to the third housing part 7 (the contact elements 9, 10 of the third housing part 7 are elastically deformable).

The housing parts 3, 4, 7 are connected to each other in such a way that a uniform ground potential is realized.

The first housing part 3 is an upper side (upper half) or a cover part and the second housing part 4 is a lower side (lower half) or a base part. The first housing part 3 and the second housing part 4 are connected to each other via a sealing surface 5 and enclose the volume 6 in a liquid-tight or, if necessary, gas-tight manner. The third housing part 7 is arranged completely inside the volume 6. The third housing part 7 serves as a mounting plate for components 2 arranged inside the volume 6. In addition, the third housing part 7 serves to divide the volume 6 into sub-volumes, whereby these are then shielded from each other by the third housing part 7.

The third housing part 7 is plate-shaped. It is designed as a formed sheet metal part.

The third housing part 7 has a plurality of elastically deformable contact elements 9, 10 in the connection regions 8 to form an electrically conductive connection between the housing parts 3, 4, 7. In a connection region 8, the third housing part 7 contacts either only the first housing part 3 (e.g. FIG. 7) or only the second housing part 4 or both housing parts 3, 4 (e.g. along the circumference 28 of the housing 1). In this case, the third housing part 7 contacts the first housing part 3 exclusively with an upper side and the second housing part 4 exclusively with a lower side.

The contact elements 9, 10, via which contact is made with the other housing parts 3, 4, are elastically deformable.

When the housing parts 3, 4, 7 are connected to form the housing 1, the contact elements 9, 10 are deformed at least or exclusively elastically (alternatively also plastically) by the housing part 3, 4 contacting the respective contact element 9, 10. This means that the contact elements 9, 10 are in an undeformed state (see e.g. FIGS. 5, 8 to 12 and 14) before the housing 1 is assembled for the first time and are then deformed during assembly (see e.g. FIGS. 13 and 15). This also means that the contact elements 9, 10 are under a preload when the housing 1 is assembled.

The contact elements 9, 10 are arranged next to each other in the connection region 8 along an extension direction 12 and separated from each other by exactly one slit 11 in each case.

A slit 11 is an opening in the third housing part 7, which extends from the top to the bottom of the third housing part 7 (see FIG. 5). The slit 11 is elongated, i.e. it has a length 13 that is greater by a factor of approx. 20 than a breadth 29.

The slits 11 of a connection region 8 are oriented parallel to each other or extend transversely to a straight (e.g. along the circumference 28, see FIG. 5) or possibly also curved course (see also FIG. 5 in the flat area 30) of the connection region 8.

The slits 11 each extend in a straight line (in one view along the height direction 16).

The slit 11 serves to ensure that the contact elements 9, 10 arranged between two slits 11 can be deformed independently of each other or independently of the area 30 of the third housing part 7 surrounding them (elastically, possibly also plastically).

The contact elements 9, 10 are arranged next to each other in the connection region 8 along an extension direction 12. The slits 11 of the contact elements 9, 10 arranged at a distance from the circumference 28 (in the flat area 30) have a length 13 of approx. 25 millimeters extending transversely to the extension direction 12. The slits 11 of the contact elements 9, 10 arranged on the circumference 28 have a length of approximately 10 millimeters.

The contact elements 9, 10 arranged on the circumference 28 have a width 14 of 15 millimeters between two slits 11. The contact elements 9, 10 arranged at a distance from the circumference 28 (in the flat area 30) have a smaller width 14 of approximately 10 millimeters between slits 11.

The slits 11 have a breadth 29 of 1 (one) millimeter extending transversely to the length 13. The breadth 29 is constant along the length 13.

The respective contact element 9, 10 is defined by the length 13 of the slits 11 and the width 14 of the contact element 9, 10, wherein the contact elements 9, 10 comprise approximately 15% of a total area 15 of the third housing part 7 (i.e. area of the upper side or area of the lower side, as a projection into a plane 18, which is defined, for example, by the circumference 28 of the third housing part 7).

The contact elements 9, 10 extend over approximately 70% of the extent of the circumference 28 of the third housing part 7.

The third housing part 7 extends essentially in a plane 18. The third housing part 7 has flat, planar areas 30 on the one hand and contact elements 9, 10 or connection regions 8 on the other. A height direction 16 extends transversely to the plane 18. The contact elements 9, 10 extend from a first height 17 of the flat areas 30 to a second height 31. The second height 31 can be above or below the plane 18 (e.g. above in FIG. 7). An amount of a distance 32 between the first height 17 and the second height 31 is, for example, 7 millimeters for the contact elements according to FIG. 7.

The surface of the contact element 9, 10, i.e. between two slits 11 and along the length 13, has a curved shape, i.e. the contact element 9, 10 has a curved or otherwise curved course along a direction running parallel to the slits 11 (see FIGS. 4, 7). As a result, a raised area with a different second height 31 is formed compared to the flat area 30 surrounding the contact elements 9, 10, which has a first height 17.

FIG. 8 shows a first embodiment of contact elements 9, 10 in a view transverse to the extension direction 12, in a view according to section VIII-VIII in FIG. 9. FIG. 9 shows the contact elements 9, 10 according to FIG. 8 in a view along the extension direction 12, in a view according to section IX-IX in FIG. 8. FIGS. 8 and 9 are described together below. Reference is made to the comments on FIGS. 1 to 7.

The surface of the contact element 9, 10, i.e. between two slits 11 and along the length 13, is curved, i.e. the contact element 9, 10 has a curved shape along a direction running parallel to the slits 11 (see FIG. 9). This forms a raised area with a different second height 31 compared to the flat area 30 surrounding the contact elements 9, 10, which has a first height 17.

In an undeformed state (i.e. before the housing 1 is joined together and before the contact elements 9, 10 are elastically deformed), the contact elements 9, 10 each have the same second height 31 along the extension direction 12. Each of the contact elements 9, 10 has a constant second height 31 along the extension direction 12.

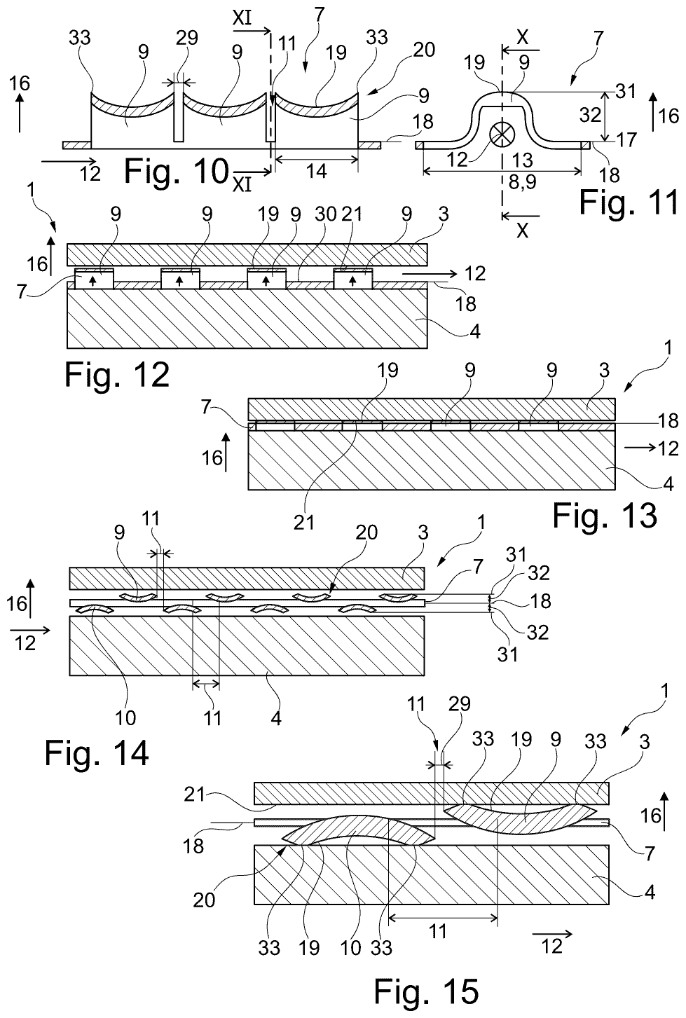

FIG. 10 shows a second embodiment of contact elements 9, 10 in a view transverse to the extension direction 12, in a view according to section X-X in FIG. 11. FIG. 11 shows the contact elements 9, 10 according to FIG. 10 in a view along the extension direction 12, in a view according to section XI-XI in FIG. 10. FIGS. 10 and 11 are described together below. Reference is made to the comments on FIGS. 8 and 9.

In contrast to the first embodiment, the contact elements 9, 10 in an undeformed state have a second height 31 that varies along the extension direction 12. The contact elements 9, 10 each have a largest second height 31 (maxima) adjacent to the two slits 11 delimiting the respective contact element 9, 10 and a smallest second height 31 (minimum) between these two largest second heights 31 (maxima). The smallest second height 31 (minimum) is greater than a first height 17 of the flat area 30.

The contact elements 9, 10 have a contact surface 19 contacting the respective housing part 3, 4 with a structure 20, wherein the structure 20 contacts the housing part 3, 4 during the elastic deformation of the contact element 9, 10 and damages its housing part surface 21. The structure 20 has sharp edges 33 (edge radius very small, neighboring surfaces of the edge 33 have an angle of approx. 40 degrees). The structure 20 is formed by the edges 33 of the contact element 9, 10 adjacent to the slit 11. These edges 33 are oriented towards the housing part 3, 4 in the undeformed state (i.e. before the housing 1 is joined together and before the contact elements 9, 10 are elastically deformed), so that the edge 33 itself makes contact with the housing part 3, 4. The surfaces of the contact element 9, 10 adjacent to the edge 33 extend at an angle of 90 and approximately 50 angular degrees to a contacted housing part surface 21 of the housing part 3, 4.

FIG. 12 shows a section of a first embodiment of a housing 1 before assembly of the housing parts 3, 4, 7 in a side view in cross-section. FIG. 13 shows the section according to FIG. 12 in the assembled state. FIGS. 12 and 13 are described together below. Reference is made to the comments on FIGS. 1 to 11.

The contact elements 9, 10 are arranged next to each other in the connection region 8 along an extension direction 12 and are deformed relative to a height direction 16 in the course of joining the housing parts 3, 4, 7. The flat area 30 of the third housing part 7 extends between the contact elements 9, 10. In an undeformed state (i.e. before the housing 1 is joined together and before the contact elements 9, 10 are elastically deformed-see FIG. 12), the contact elements 9, 10 each have the same second heights 31 along the extension direction 12. During the assembly of the housing 1, these second heights 31 are contacted by the first housing part 3 and successively deformed so that the second heights 31 are reduced (see FIG. 13). The contact elements 9, 10 are under a preload in the deformed state.

FIG. 14 shows a section of a second embodiment of a housing 1 before assembly of the housing parts 3, 4, 7 in a side view in cross-section. FIG. 15 shows the section according to FIG. 14 in the assembled state. FIGS. 14 and 15 are described together below. Reference is made to the comments on FIGS. 1 to 13.

The contact elements 9, 10 are arranged next to each other in the connection region 8 along an extension direction 12 and are deformed relative to a height direction 16 in the course of the connection of the housing parts 3, 4, 7.

Of two contact elements 9, 10 arranged next to each other, a first contact element 9 contacts only the first housing part 3 and a second contact element 10 contacts only the second housing part 4.

In addition to the (first) slits 11 arranged between the contact elements 9, 10, further (second) slits 11 are provided, which are arranged at the respective ends of the length 13 of the (first) slits 11 and extend transversely thereto. A transition between the contact element 9, 10 and the flat area 30 surrounding the contact element 9, 10 is narrowed by these (second) slits 11, but not cut through.

The third housing part 7 extends in the connection region 8 along an extension direction 12 in a (central) plane 18. Of two contact elements 9, 10 arranged next to each other, a first contact element 9 is oriented from the central plane 18 towards the first housing part 3 and a second contact element 10 is oriented from the central plane 18 towards the second housing part 4. This means that these contact elements 9, 10 extend in opposite height directions 16 relative to the center plane 18 (first height 17) to a second height 31 of the same absolute amount in each case.

In an undeformed state (i.e. before the housing 1 is joined together and before the contact elements 9, 10 are elastically deformed—see FIG. 14), the first contact elements 9 each have the same second height 31 along the extension direction 12. During the assembly of the housing 1, these second heights 31 are contacted by the first housing part 3 and successively deformed so that the second heights 31 are reduced (see FIG. 15). The same applies to the second contact elements 10.

In an undeformed state (i.e. before the housing 1 is joined together and before the contact elements 9, 10 are elastically deformed), the contact elements 9, 10 each have different second heights 31 along the extension direction 12. The second heights 31 differ from one another by 200% of the maximum distance 32 (between the greatest second height 31 and the first height 17). The contact elements 9, 10 extend relative to the (central) plane 18 (first height 17) in opposite height directions 16 to a second height 31 of equal magnitude in each case. The contact elements 9, 10 are under a preload in the deformed state.

The contact elements 9, 10 have a contact surface 19 contacting the respective housing part 3, 4 with a structure 20, wherein the structure 20 contacts the housing part 3, 4 during the elastic deformation of the contact element 9, 10 and damages its housing part surface 21. The structure 20 has sharp edges 33 (edge radius very small, neighboring surfaces of the edge 33 have an angular amount of approx. 100 degrees). The structure 20 is formed by the edges 33 of the contact element 9, 10 adjacent to the slit 11. These edges 33 are oriented towards the housing part 3, 4 in the undeformed state (i.e. before the housing 1 is joined together and before the contact elements 9, 10 are elastically deformed), so that the edge 33 itself contacts the housing part 3, 4. The surfaces of the contact element 9, 10 adjacent to the edge 33 extend at an angle of approximately 50 degrees to a contacted housing part surface 21 of the housing part 3, 4.

In an undeformed state, the contact elements 9, 10 have a second height 31 that varies along the extension direction 12. The contact elements 9, 10 each have a largest second height 31 (maxima) adjacent to the two slits 11 delimiting the respective contact element 9, 10 and a smallest second height 31 (minimum) between these two largest second heights 31 (maxima). The smallest second height 31 (minimum) is greater than a first height 17 of the flat area 30.

The electrically conductive connection between the first housing part 3 and the second housing part 4 is (also) ensured by the third housing part 7. However, screws are also possible as connecting elements 26, which are used to connect the first housing part 3 to the second housing part 4 and to ensure the electrically conductive connection.

1. An EMC housing for an electrical component, comprising at least a first housing part and a second housing part, which are connected to one another via a sealing surface and together enclose a volume of the housing in a liquid-tight manner, a plate-shaped third housing part being arranged between the first housing part and the second housing part within the volume; wherein the third housing part has a plurality of elastically deformable contact elements in at least one connection region with at least one of the first housing part and the second housing part for forming an electrically conductive connection between the housing parts; wherein, when the housing parts are interconnected to form the housing, the contact elements are elastically deformed by the housing part contacting the respective contact element.

2. The EMC housing according to claim 1, wherein the plurality of contact elements are arranged next to one another in the connection region and separated from one another by at least one slit in each case.

3. The EMC housing according to claim 2, wherein the contact elements are arranged next to one another in the connection region along an extension direction and the at least one slit has a length of 5 to 50 millimeters extending transversely to the extension direction.

4. The EMC housing according to claim 2, wherein at least one of the contact elements between two slits has a width of 5 to 20 millimeters.

5. The EMC housing according to claim 2, wherein the contact elements are defined by the length of the slits and width of the contact elements, wherein the contact elements comprise between 0.5% and 80% of a total area of the third housing part.

6. The EMC housing according to claim 1, wherein the contact elements are arranged next to one another in the connection region along an extension direction and are deformed relative to a height direction by the connection of the housing parts; wherein the contact elements in an undeformed state have the same or different heights along the extension direction.

7. The EMC housing according to claim 1, wherein, of two contact elements arranged next to one another, a first contact element contacts only the first housing part and a second contact element contacts only the second housing part.

8. The EMC housing according to claim 1, wherein the third housing part extends in the connection region along an extension direction in a central plane and, of two contact elements arranged next to one another, a first contact element is oriented starting from the central plane towards the first housing part and a second contact element is oriented starting from the central plane towards the second housing part.

9. The EMC housing according to claim 1, wherein the contact elements are arranged next to one another in the connection region along an extension direction and are deformed relative to a height direction by the connection of the housing parts; wherein at least one contact element in an undeformed state has a height varying along the extension direction.

10. The EMC housing according to claim 1, wherein at least one contact element has a contact surface contacting the respective housing part with a structure, wherein the structure contacts the housing part during the elastic deformation of the contact element and damages its housing part surface.

11. The EMC housing according to claim 1, wherein the third housing part consists of a metallic material.

12. A housing part of an EMC housing according to claim 1, wherein the housing part is the third housing part.

13. The use of an EMC housing according to claim 1 for an inverter as an electrical component.
